(19) United States
(12) Patent Application Publication
(10) Pub. No.: US 2012/0264267 A1
(43) Pub. Date: Oct. 18, 2012

(54) METHOD FOR FABRICATING MOS TRANSISTOR

(76) Inventors: Tsuo-Wen Lu, Kaohsiung City (TW); Gin-Chen Huang, New Taipei City (TW); Shao-Wei Wang, Taichung City (TW); Yu-Ren Wang, Tainan City (TW); Ya-Chi Cheng, Kaohsiung City (TW)

(21) Appl. No.: 13/084,564

(22) Filed: Apr. 12, 2011

(51) Int. Cl. H01L 21/336

(52) U.S. Cl. 438/285; 257/E21.409

(57) ABSTRACT

A method of fabricating a MOS transistor includes the steps of: providing a substrate; forming a gate structure on the substrate; forming a first spacer on the sidewall of the gate structure and forming at least a recess within the substrate next to the first spacer; performing an oxygen-containing process to form an oxygen-containing layer on the surface of the recess; performing a cleaning process to remove the oxygen-containing layer; performing an epitaxial process to form an epitaxial layer in the recess; and removing the first spacer.

### BACKGROUND OF THE INVENTION

1. Field of the Invention

The present invention is related to a method of fabricating a MOS transistor, and more specifically, to a method of fabricating a MOS transistor including an oxygen-containing process which enables the interface between the epitaxial layer and the substrate to not be passivated to an arc shape after a pre-baking process is performed.

2. Description of the Prior Art

As known in the art, strained silicon technologies have been introduced in the MOS manufacturing process in order to increase the mobility of electrons or holes, thereby attaining higher performance of a semiconductor device. For example, taking advantage of the lattice constant of a SiGe layer being different from that of Si, a strain occurs in the silicon layer growing on the SiGe layer. Since SiGe has a larger lattice constant than Si, the band structure of Si is altered, thereby increasing the mobility of the carriers.

FIG. 1 schematically depicts a cross-sectional view of a conventional MOS transistor applying epitaxial technologies. As shown in FIG. 1, the method of fabricating the MOS transistor 100 includes: forming a gate structure 120 having a gate dielectric layer 122, a gate electrode 124 and a cap layer 126 on a substrate 110, forming a spacer 130, a recess 140 and an epitaxial layer 150. The epitaxial layer 150 may be, for instance, a silicon germanium layer or a silicon carbide layer. Otherwise, an insulating trench structure 10 may be formed to electrically isolate each MOS transistor.

However, the interface between the silicon germanium layer or the silicon carbide layer and the substrate 110 is easily passivated into an arc-shaped structure during manufacturing because of some factors. This arc-shaped structure gives rise to a larger distance d between the epitaxial layer 150 and reduces the stress force on the gate channel 160 from the epitaxial layer 150, resulting in low transferring velocity of carriers, thereby affecting the performance of the MOS transistor 100.

According to the above, a fabricating method to solve the aforementioned problems of passivation occurring while a MOS transistor is miniaturized is needed in the field.

### SUMMARY OF THE INVENTION

The purpose of the present invention is to provide a method of fabricating a MOS transistor and a method of forming an epitaxial layer to solve the problem of the interface passivation between the epitaxial layer and the substrate.

According to a preferred embodiment of the present invention, a method of fabricating a MOS transistor includes the following steps. A substrate is provided. Agate structure is formed on the substrate. A first spacer is formed on the sidewall of the gate structure and at least a recess is formed within the substrate next to the first spacer
An oxygen-containing process is performed to form an oxygen-containing layer on the surface of the recess. A cleaning process is performed to remove the oxygen-containing layer. An epitaxial process is performed to form an epitaxial layer in the recess. The first spacer is removed.

According to the above, the present invention provides a method of fabricating a MOS transistor and a method of forming an epitaxial layer, both of which include performing an oxygen-containing process on the surface of recesses to form an oxygen-containing layer on each recess that keeps the shape of the interface between the recess and the substrate as a square corner instead of passivating to an arc shape after the epitaxial layer is formed.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a cross-sectional view of a conventional MOS transistor applying epitaxial technologies.

FIG. 2 schematically depicts a flowchart of fabricating a MOS transistor applying epitaxial technologies according to one preferred embodiment of the present invention.

FIG. 3 to FIG. 8 schematically depict a method of fabricating a MOS transistor applying epitaxial technologies according to one preferred embodiment of the present invention.

FIG. 9 schematically depicts a distribution diagram of the interface between the epitaxial layer and the substrate of a MOS transistor with arc-shape and an O2 strip process according to one embodiment of the present invention.

FIG. 10 schematically depicts a cross-sectional view of a CMOS transistor applying epitaxial technologies according to one preferred embodiment of the present invention.

### DETAILED DESCRIPTION

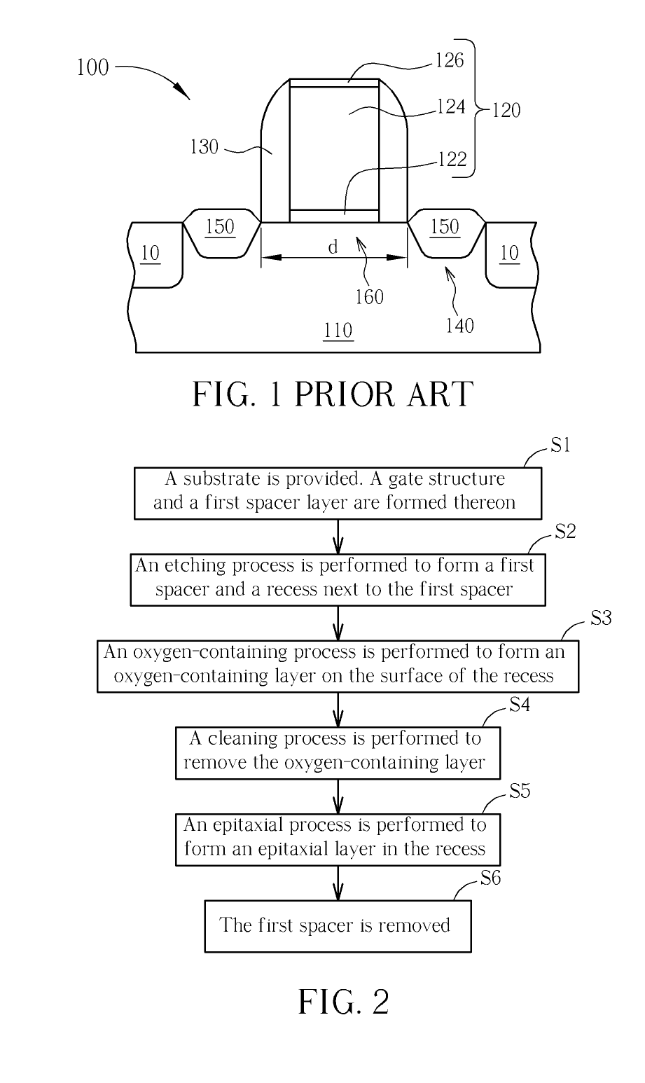

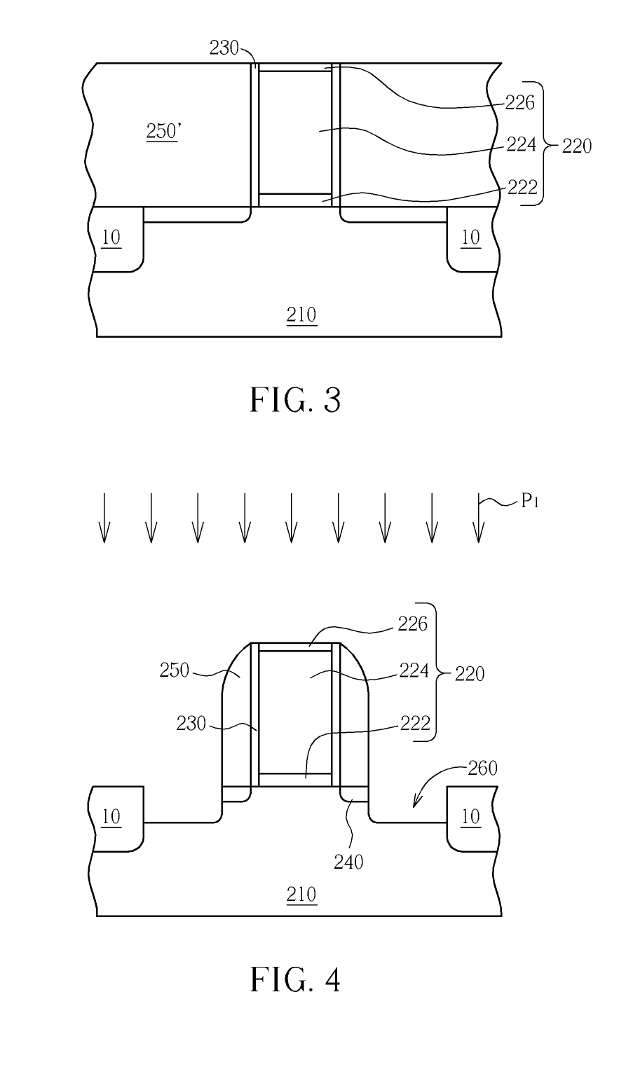

FIG. 2 schematically depicts a flowchart of fabricating a MOS transistor applying epitaxial technologies according to one preferred embodiment of the present invention. FIG. 3 to FIG. 8 schematically depicts a method of fabricating a MOS transistor applying epitaxial technologies according to one preferred embodiment of the present invention. Referring to FIG. 2 and FIG. 3 to FIG. 8, a method of fabricating the MOS transistor 200 includes: As shown in Step S1 and FIG. 3, a substrate 210, for instance a semiconductor substrate such as silicon substrate, is provided. A gate structure 220 is formed on the substrate 210, and contains a gate dielectric layer 222, a gate electrode 224, and a cap layer 226 sequentially formed. The detailed forming methods and materials being applied are known to those skilled in the art, and therefore are not described herein.

At least a second spacer 230 is selectively formed on the sides of the gate structure 220. A lightly doped ion implantation is performed to form a lightly doped source/drain region 240 within the substrate 210 next to the gate structure 220, wherein the second spacer 230 may include, for example, a single or a multi composite structure composed of silicon nitride, silicon oxide etc. The second spacer 230 can be used as a hard mask for lightly doped ion implantation to automatically align and define the lightly doped source/drain region 240. Then, a first spacer layer 250′ is deposited beside the gate structure 220 (or the second spacer 230). In this case, the first spacer layer 250′ is a silicon nitride layer, particularly being formed by a precursor of hexachlorosilane, but in anther case, the first spacer 250 may be other materials.

As shown in Step S2 and FIG. 4, the first spacer 250 is formed by etching. An etching process P1 is performed, which may be a dry etching process, a dry etching process paired with a wet etching process etc., to form a recess 260 within the substrate 210 next to the first spacer 250 by using the first spacer 250 as a hard mask. Besides, a wet etching process may be selectively performed for further etching the recess 260.

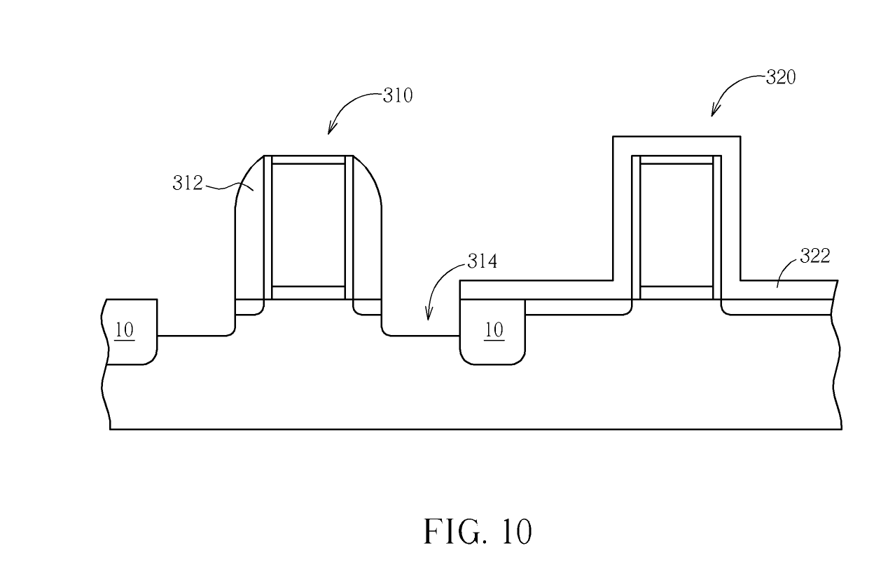

It is worthy of note that the present invention illustrates a method of fabricating a single MOS transistor, hence the first spacer 250 formed by a precursor of hexachlorosilane is a spacer of the MOS transistor 200. However, in the CMOS transistor process, the hard mask formed by a precursor of hexachlorosilane can be simultaneously applied to a hard mask for protecting a first conductive MOS transistor from being etched and to a spacer of a second conductive MOS transistor to etch a recess needed for silicon epitaxy. As shown in FIG. 10, a deposition process using hexachlorosilane as a precursor and a patterning process are performed to conformally cover a dielectric layer 322 on the MOS transistor 320 and form a first spacer 312 on the MOS transistor 310, so a recess 314 can be formed by using the dielectric layer 322 and the first spacer 312 as hard masks. In one embodiment, the MOS transistor 320 may be an n-type MOS transistor, the MOS transistor 310 may be a p-type MOS transistor, and the epitaxial layer may be a silicon-germanium layer. In another embodiment, the MOS transistor 320 may be a p-type MOS transistor, the MOS transistor 310 may be an n-type MOS transistor, and the epitaxial layer may be a silicon-carbide layer. Otherwise, the dielectric layer 322 and the first spacer 312 include a silicon nitride layer formed by a precursor of hexachlorosilane, but in another case, the dielectric layer 322 and the first spacer 312 may be other materials.

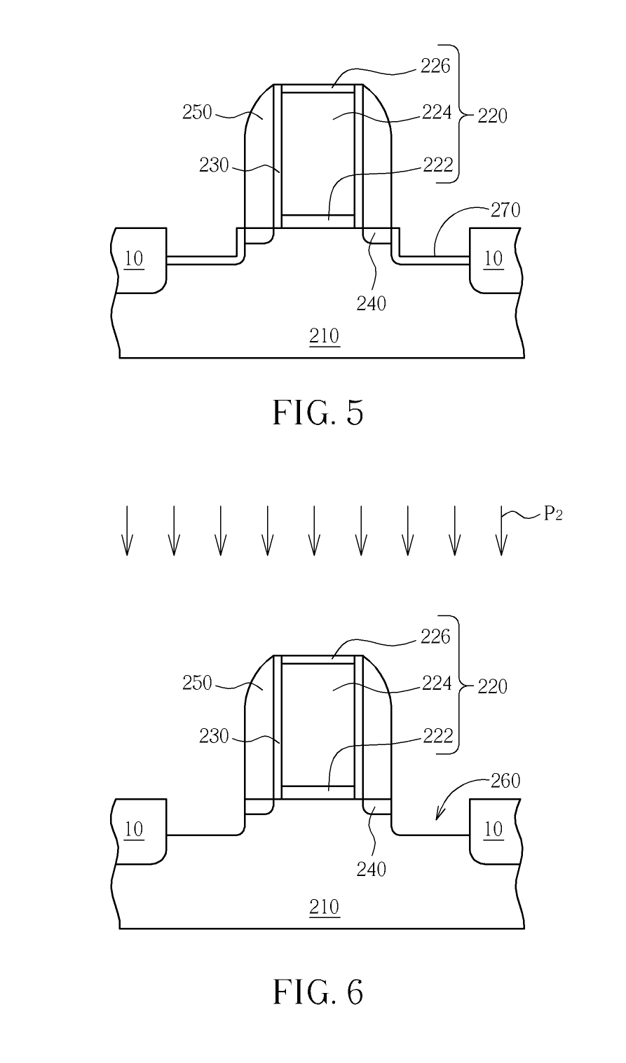

As shown in Step S3 and FIG. 5, an oxygen-containing process is performed to form an oxygen-containing layer 270 on the surface of the recess 260, wherein the oxygen-containing process includes an O2 strip process, a decoupled plasma oxidation (DPO) process, a chemical oxide process or combinations thereof. In a preferred embodiment, the O2 strip process is performed at a temperature of 200° C. and the decoupled plasma oxidation process is performed at room temperature. Moreover, the oxygen-containing layer 270 is formed on the surface of the recess 260 in this embodiment, but the oxygen-containing layer 270 may be formed by surface interaction. In a preferred embodiment, the thickness of the oxygen-containing layer 270 is in the range of 20˜50 A.

As shown in Step S4 and FIG. 6, a cleaning process P2 is performed to remove the oxygen-containing layer 270, wherein the cleaning process P2 may be, for instance, a pre-cleaning process, and the cleaning process P2 may use the diluted hydrofluoric acid solution as a cleaner, but is not limited thereto. It is worthy of note that, in this embodiment, the oxygen-containing process is better performed under a temperature of 250° C. because the oxygen-containing layer 270 formed at this temperature is easier to be removed by the sequential cleaning process P2. However, in another embodiment, the oxygen-containing process may be performed higher than a temperature of 250° C.—at a temperature of 700° C. for example—but the oxygen-containing layer 270 formed at this temperature needs the cleaning process P2 to be performed for a longer operating time in order to totally remove the oxygen-containing layer 270.

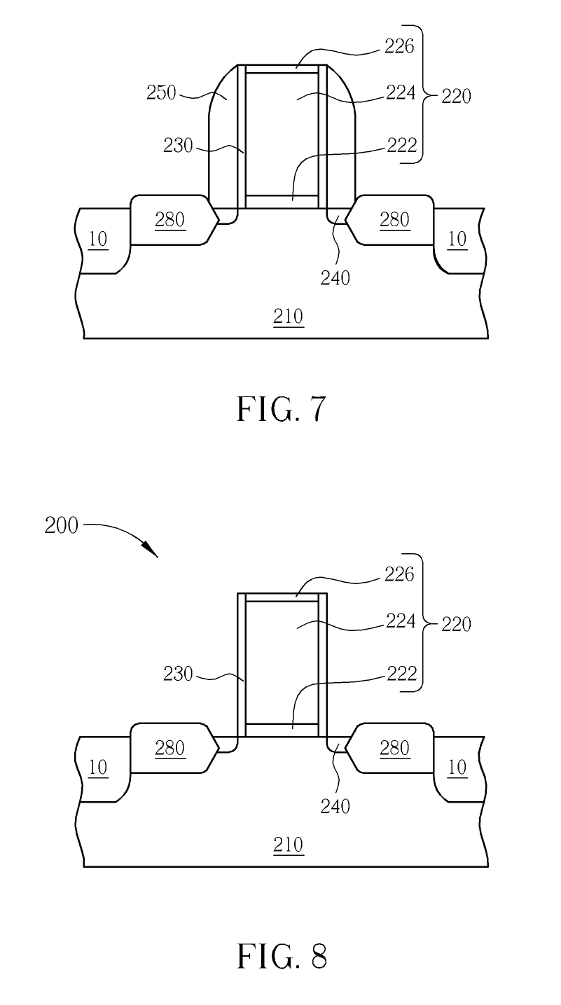

As shown in Step S5 and FIG. 7, an epitaxial process is performed to form an epitaxial layer 280 in the recess 270. In this case, the epitaxial layer 280 may be a silicon germanium epitaxial layer, but in another case the epitaxial layer 280 may be a silicon carbide epitaxial layer. Besides, the shape of the epitaxial layer 280 is a hexagon in this case, but the shape of the epitaxial layer 280 may be an octagon or other shapes. Moreover, the epitaxial process may include pre-bake, Si seed layer deposition, SiGe epitaxial growth etc. and the epitaxial process may be performed at a temperature equal to or higher than 800° C. with hydrogen imported. It should to be noted that, due to the oxygen-containing process being performed, even if the epitaxial process is performed at a temperature equal to or higher than 800° C., the interface between the epitaxial layer 280 and the substrate 210 can also remain in the shape of a square corner instead of passivating to the arc shape in the prior art. Thus, the problem of the bad performance of the MOS transistor 100 resulting from the lower transferring velocity of the transistor carriers caused by the over-length of the gate channel and the distance between the epitaxial layer of the source/drain region is avoided.

As shown in Step S6 and FIG. 8, the first spacer 250 is selectively removed, meaning the MOS transistor 200 having the improved interface between the epitaxial layer 280 and the substrate 210 is formed at this point. The epitaxial layer 280 may be formed within a doped source/drain region, be simultaneously formed with the conductive dopant in a source/drain region, or doping may be performed after the epitaxial layer 280 is formed to form a source/drain region. Furthermore, after the epitaxial layer 280 is formed, a metal silicide may be formed on the epitaxial layer 280, or a contact etch stop layer (CESL) may be further formed on the metal silicide. Both these modifications fall within the scope of the present invention.

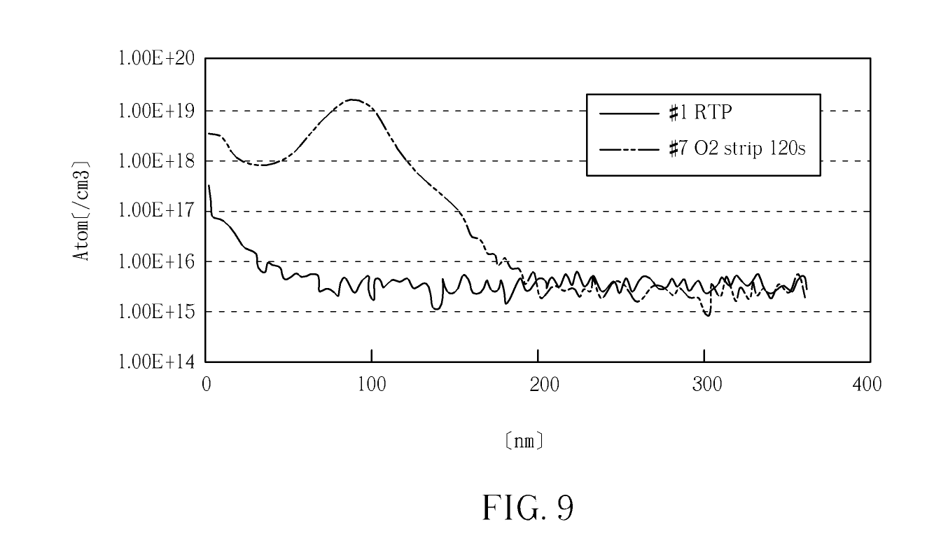

FIG. 9 schematically depicts a distribution diagram of the interface between the epitaxial layer and the substrate of a MOS transistor with arc-shape and an O2 strip process according to one embodiment of the present invention. HCD based SiN owns higher Cl concentration >1E21 atom/cm3. The surface of Si recess is easily forming a higher Cl content or hydrophilic interface after pre-SiGe wet clean. During baking 800 C process, the surface of Si recess becomes instable leading to silicon migration. As shown in FIG. 9, there's no Cl peak observed on arc-shape condition because the Cl is interacted with the Si surface leading to another stable arc-shape while baking 800 C process. After that, the surface of Si recess has no ability of re-absorbing Cl even if the SiGe precursor includes Cl composition. The O2 strip process in the present invention may reduce the higher Cl content or hydrophilic interface after pre-SiGe wet clean. In general, the peak of Cl is supposed coming from the SiGe precursor includes Cl composition. Therefore, the passivation in the interface of the epitaxial layer and the substrate is also avoided and the performance of the MOS transistor is improved.

According to the above, the present invention provides a method of fabricating a MOS transistor including an oxygen-containing process being performed on the surface of the recess to form an oxygen-containing layer, which is used to change the chemical distribution in the surface of the recess. This makes the interface between the sequentially formed epitaxial layer and the substrate remain in the shape of a square corner, thereby solving the problem of passivating to an arc shape in the prior art, hence improving the performance of MOS transistors or other electronic devices manufactured by the method of forming the epitaxial layer.

Those skilled in the art will readily observe that numerous modifications and alterations of the device and method may be made while retaining the teachings of the invention.

What is claimed is:

1. A method of fabricating a MOS transistor, comprising:
providing a substrate;
forming a gate structure on the substrate;
forming a first spacer on the sidewall of the gate structure and forming at least a recess within the substrate next to the first spacer;
performing an oxygen-containing process to form an oxygen-containing layer on the surface of the recess;
performing a cleaning process to remove the oxygen-containing layer;
performing an epitaxial process to form an epitaxial layer in the recess; and
removing the first spacer.

2. The method of fabricating a MOS transistor according to claim 1, wherein the gate structure comprises a gate dielectric layer, a gate electrode, and a cap layer.

3. The method of fabricating a MOS transistor according to claim 1, wherein the first spacer comprises silicon nitride.

4. The method of fabricating a MOS transistor according to claim 1, further comprising forming at least a second spacer on the sidewall of the gate structure after the gate structure is formed.

5. The method of fabricating a MOS transistor according to claim 4, further comprising performing a lightly doped ion implantation to form a lightly doped source/drain region within the substrate next to the gate structure after the second spacer is formed.

6. The method of fabricating a MOS transistor according to claim 1, wherein the first spacer is formed by a precursor of hexachlorosilane (HCD).

7. The method of fabricating a MOS transistor according to claim 1, wherein the oxygen-containing process is performed under a temperature of 300° C.

8. The method of fabricating a MOS transistor according to claim 1, wherein the oxygen-containing process comprises an O2 stripping process.

9. The method of fabricating a MOS transistor according to claim 8, wherein the O2 strip process is performed at a temperature of 200° C.

10. The method of fabricating a MOS transistor according to claim 1, wherein the oxygen-containing process comprises a decoupled plasma oxidation (DPO) process.

11. The method of fabricating a MOS transistor according to claim 10, wherein the decoupled plasma oxidation process is performed under a temperature of 300° C.

12. The method of fabricating a MOS transistor according to claim 1, wherein the oxygen-containing process comprises a chemical oxide process.

13. The method of fabricating a MOS transistor according to claim 1, wherein the cleaning process comprises a pre-cleaning process.

14. The method of fabricating a MOS transistor according to claim 1, wherein the cleaning process comprises using diluted hydrofluoric acid as a cleaner.

15. The method of fabricating a MOS transistor according to claim 1, wherein the epitaxial process comprises a pre-baking process.

16. The method of fabricating a MOS transistor according to claim 15, wherein the pre-baking process is performed at a temperature equal to or higher than 800° C.

17. The method of fabricating a MOS transistor according to claim 1, wherein the epitaxial layer is a silicon-germanium epitaxial layer or a silicon-carbide epitaxial layer.

18. The method of fabricating a MOS transistor according to claim 1, wherein the thickness of the oxygen-containing layer ranges between 20 A and 50 A.

19. The method of fabricating a MOS transistor according to claim 1, after forming a first spacer on the sidewall of the gate structure and forming at least a recess within the substrate next to the first spacer, further comprising:
performing a wet etching process to etch the recess.
